(19) United States
(12) Patent Application Publication
(10) Pub. No.: US 2003/0223596 A1
(43) Pub. Date: Dec. 4, 2003

(54) Audio multi-channel equalizer

(76) Inventor: Thomas Zint, Willich (DE)

Correspondence Address: COLLARD & ROE, P.C., 1077 Northern Boulevard, Roslyn, NY, 11576-1696, US

(21) Appl. No.: 10/202,353

(22) Filed: Jul. 24, 2002

(30) Foreign Application Priority Data
May 31, 2002 (DE) 102 24 492.8

(51) Int. Cl. H03G 5/00

(52) U.S. Cl. 381/103; 381/98

(57) ABSTRACT

An audio multi-channel equalizer having a plurality of bandpass filters for subdividing an audio signal into a plurality of channels. The equalizer also includes level controllers associated with the channels and optical level-indicating means. The optical level indicating means contains semiconductor switches connected to the outputs of the bandpass filters for activation of optical indications. There is also a reference voltage generator which corresponds substantially to the average signal level of the channels and which is connected commonly to all semiconductor switches.

### BACKGROUND OF THE INVENTION

1. Field of the Invention

The present invention relates to an audio multi-channel equalizer with a plurality of bandpass filters for subdividing an audio signal into a plurality of channels. There are also level controllers associated with the channels and an optical level-indicating means, which contain semiconductor switches connected to the outputs of the bandpass filters for activation of optical indications.

These equalizers, which are used in the form, of graphic equalizers, enable a user to adjust the channels and to balance them relative to one another on the basis of optical indications of the respective channel level. Various means are conceivable as optical indications. Some examples of optical indicators are measuring instruments or LEDs. Optical monitoring of the channel levels is also referred to as visual feedback or closed-loop indication.

2. The Prior Art

An audio multi-channel equalizer, of the type mentioned in the introduction, with optical indication of the channel level is known, for example, from U.S. Pat. No. 5,737,428. To activate the respective optical indications, this equalizer provides peak-value detectors, each of which comprise a sensing diode and a storage capacitor. These peak-value detectors are connected between the output of the respective bandpass filter and the semiconductor switch for activation of the associated optical indication, and are designed to discriminate the relative maximum of the signal of the respective channel from the many other signals. Regarding the optical channel-level indications, this known equalizer unfortunately has a large component expense which then discriminates the respective signals from one another for the purpose of optical indication.

### SUMMARY OF THEE INVENTION

One object of the present invention is to provide an audio multi-channel equalizer which has a simpler optical level-indicating means than the prior art. This design results in a less costly configuration, while ensuring reliably of the intended optical indication.

Accordingly, the invention is a device for generation of a reference voltage which corresponds substantially to the average signal level of the channels and which is connected commonly to all semiconductor switches.

Thus, the inventive equalizer avoids the use of complex peak-value detectors and directly exploits the actual audio input signal in combination with the semiconductor switches for optical channel-level indication. These switches are used as comparators and are activated whenever the actual input-signal level exceeds the average signal level or a common signal-level threshold. The comparator effect creates an indicator of when the actual input signal exceeds the average signal level, by the fact that the longer the semiconductor switch is activated (by comparison with one period of the input signals), so also is the optical indication more intense or, brighter, whereby a reliable indication of the signal level of the individual channels relative to one another is available to the user.

There can also be a power source which acts as a device for generating a reference voltage, corresponding substantially to the average signal level of the channels. To achieve automatic adjustment of the reference voltage to the average signal level of the channels, this power source is preferably designed as a slow-response power source. To configure the optical indications of the inventive equalizer universally, the power source can be designed to be adjustable, meaning that its supply voltage can be appropriately adjusted so that it can be matched to the level of the audio input signal.

The semiconductor switch can be a transistor or any other known type switch.

The optical indications can also be of any desired intensity indications in the form of light-emitting diodes, but these indications can also be of any desired type. Furthermore, the inventive equalizer is preferably designed as a graphic equalizer.

### BRIEF DESCRIPTION OF THE DRAWINGS

Other objects and features of the present invention will become apparent from the following detailed description considered in connection with the accompanying drawing. It is to be understood, however, that the drawing is designed as an illustration only and not as a definition of the limits of the invention.

In the drawing, wherein similar reference characters denote similar elements throughout the view:

FIG. 1 shows a schematic circuit diagram of an audio multi-channel equalizer.

### DETAILED DESCRIPTION OF THE PREFERRED EMBODIMENT

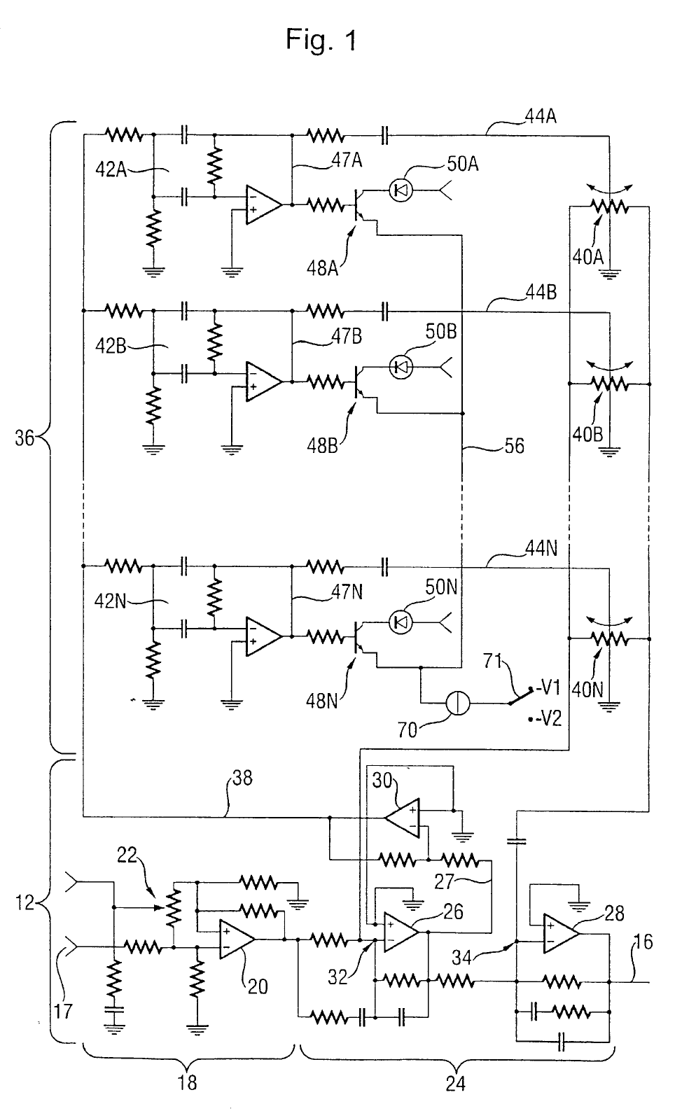

As FIG. 1 shows, the audio multi-channel equalizer contains an amplifier 12 with an input 14 and an output 16. Amplifier 12 has a first amplifier control stage 18 having an operational amplifier 20 and an amplifier controller 22 in the form of a potentiometer in the feedback loop. Amplifier control stage 18 feeds a two-stage amplifier 24, which contains first and second operational amplifiers 26, 28 respectively. First stage 26 has an output 27, which is connected to an inverting feedback amplifier 30. Bridge circuit 36 includes amplifier 24 disposed in bridge circuit 36 between an input 32 of first stage 26 and an input 34 of second stage 28. Amplifier 30 or bridge circuit 36 generates an output signal for bridge circuit 36 on line 38.

Bridge circuit 36 contains a plurality of level controllers 40A to 40N, a corresponding plurality of filter networks 42A to 42N, or in other words one for each of a plurality of frequency bands, and RC-coupled control lines 44A to 44N, which are connected to center tap 46 of level controller 40 and to the corresponding outputs 47A to 47N of filters 42A to 42N.

Bridge 36 also contains a plurality of driver amplifiers 48A to 48N, which are connected to light-emitting diodes 50A to 50N respectively. Driver amplifiers 48A to 48N are based on semiconductor switches, which can be three-lead elements in the form of transistors. Each driver amplifier 48A to 48N or semiconductor switch is connected via a resistor to the output of a filter network 42A to 42N respectively.

All driver amplifiers 48A to 48N are connected via one lead such as the emitter electrode to a common line 56, to which there is applied to common line 56 reference voltage whose magnitude is substantially the average signal level of the channels of the equalizer. This reference voltage, which is used as the threshold voltage, is supplied by a generating device in the form of a power source 70, whose voltage supply can be toggled between a voltage minus V₁ and V₂, specifically via switch 71.

Power source 70 is preferably designed as a slow-response power source, so that the reference voltage can be automatically matched to the average signal level of the channels. In turn, the average number of active driver amplifiers 48A to 48N and of LEDs 50A to 50N activated thereby are limited at any time to a small number thereof corresponding to the channels with the highest average signal levels.

Because the semiconductor switches or driver amplifiers, which work as comparators, are connected to a common threshold level or to a common pulling voltage, the respective semiconductor switch is activated whenever the actual input signal level exceeds the common threshold level. The higher the actual input signal level lies above the common threshold, the longer the corresponding switch is activated compared with one period of the input signals and thus the greater is the perceptible brightness of the associated optical indicating means, or LED.

Accordingly, while at least one embodiment of the present invention has been shown and described, it is to be understood that many changes and modifications may be made thereunto without departing from the spirit and scope of the invention as defined in the appended claims.

What is claimed is:

1. An audio multi-channel equalizer comprising:
a) a plurality of bandpass filters for subdividing a signal into a plurality of channels;
b) a plurality of level controllers in communication with said plurality of bandpass filters;
c) an optical level indicating means coupled to said plurality of level controllers, said optical level indicating means comprising a plurality of semi-conductor switches with each of said plurality of semi-conductor switches being coupled to an output of said plurality of bandpass filters;
d) a plurality of optical indicators which are in communication with said plurality of said semi-conductor switches; and
e) a reference voltage generator which generates a voltage substantially similar to an average signal levels of said plurality of channels, wherein said device is connected commonly via a line to all of said plurality of semiconductor switches.

2. The equalizer as in claim 1, wherein said reference voltage generator is a power source.

3. The equalizer as in claim 2, wherein said power source is a slow response power source for automatic adjustment of a reference voltage to an average signal level of said plurality of channels.

4. The equalizer as in claim 1, wherein said plurality of semiconductor switches are transistors.

5. The equalizer as in claim 1, wherein said plurality of optical indicators are light-emitting diodes.

6. The equalizer as in claim 1, wherein said equalizer is a graphic equalizer.

7. An audio multi-channel equalizer comprising:
a) a plurality of bandpass filters for subdividing a signal into a plurality of channels;
b) a plurality of level controllers in communication with said plurality of bandpass filters;
c) a plurality of semi-conductor switches coupled to said plurality of controllers and forming an optical level indicator, with each of said plurality of semi-conductor switches being coupled to an output of said plurality of bandpass filters;
d) a plurality of optical indicators which are in communication with said plurality of said semi-conductor switches;
e) a reference voltage generator which generates a voltage substantially similar to an average signal levels of said plurality of channels, wherein said device is connected commonly via a line to all of said plurality of semiconductor switches.
